(19) United States
(12) Patent Application Publication
(10) Pub. No.: US 2010/0025230 A1
(43) Pub. Date: Feb. 4, 2010

(54) Vacuum Treatment Apparatus, A Bias Power Supply And A Method Of Operating A Vacuum Treatment Apparatus

(75) Inventors: Arutiun P. Ehiasarian, Sheffield (GB); Roel Tietema, Venlo (NL); Papken E. Hovsepian, Sheffield (GB); Dave Doerwald, Nijmegen (NL); Rafal Bugyi, Warszawa (PL); Andrzej Klimczak, Warszawa (PL)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignees: Hauzer Techno Coating BV, LL Venlo (NL); Sheffield Hallam University, Sheffield (GB); Huettinger Elctronic Sp. z.o.o., Zielonka (PL)

(21) Appl. No.: 12/296,897

(22) PCT Filed: Apr. 10, 2007
(86) PCT No.: PCT/EP2007/003181

§ 371 Date: Oct. 15, 2009

(30) Foreign Application Priority Data
Apr. 11, 2006 (GB) 0607269.8

(51) Int. Cl. C23C 14/34

(52) U.S. Cl. 204/192.12; 204/298.08; 204/298.03

(57) ABSTRACT

A vacuum treatment apparatus (10) for treating at least one substrate (12) and comprising a treatment chamber (14), at least one cathode (16), a power supply (18) associated with the cathode for generating ions of a material present in the gas phase in the chamber and/or ions of a material of which the cathode is formed, a substrate carrier (20) and a bias power supply for applying a negative bias to the substrate carrier and any substrate present thereon, whereby to attract said ions to said at least one substrate, said cathode power supply being adapted to apply relatively high power pulses of relatively short duration to said cathode at intervals resulting in lower average power levels comparable with DC operation, e.g. in the range from ca. 1 KW to 100 KW, is characterized in that the bias power supply is adapted to permit a bias current to flow at a level corresponding generally to the average power level, and in that an additional voltage supply of relatively low inductive and resistive impedance is associated with the bias power supply for supplying a bias voltage adapted to the power of the relatively high power pulses when said relatively high power pulses are applied to said at least one cathode.

The present invention relates to a vacuum treatment apparatus, to a bias power supply for use in a vacuum treatment apparatus and to a method of operating a vacuum treatment apparatus.

Vacuum treatment apparatus for applying metallic or ceramic coatings to metal or plastic articles is well known. For example such coatings can be applied by PVD (Physical Vapour Deposition), CVD (Chemical Vapour Deposition) or PACVD (Plasma-Assisted Chemical Vapour Deposition) apparatus. In the field of PVD coating processes vacuum treatment apparatus for applying coatings to substrates by means of magnetron sputtering or arc sputtering are particularly well known, and indeed such apparatus also includes combined magnetron sputtering and arc deposition systems and modifications of these systems which also enable PACVD to be carried out in the same apparatus.

Central to a magnetron sputtering device is a cathode which is generally of a metal but which can also be of a compound material, such as tungsten carbide. The cathode, which has an associated cathode power supply, is placed inside a vacuum chamber, generally at a sidewall thereof, and the chamber is filled with an inert gas, such as argon, at a substantially reduced pressure relative to atmospheric pressure. An article or articles to be coated, also referred to as substrates, are present inside the vacuum chamber on a substrate carrier and a bias power supply is used to apply a negative bias to the substrate carrier, and thus to the articles, so that ions generated from the cathode are attracted towards the articles.

In conventional magnetron sputtering apparatus using regular DC operation, the power applied to the cathode or cathode can be in the range between 1 to 100 kW, or indeed more or less, but is typically for example 16 to 20 kW per cathode in an HTC 1200 machine sold by Hauzer Techno Coating BV of Venlo, Netherlands. In the case of DC sputtering, such an average power, for example 20 kW, yields an average current flowing to the substrate carrier of about 4 to 10 A supplied by the bias power supply applied to the substrate carrier, which normally has to maintain a bias voltage in the range from 0 to 1200 V during sputtering as well as during metal ion etching and has to be able to do so while permitting a current of the required magnitude to flow.

One danger involved in the operation of such magnetron sputtering apparatus is that arcing may take place at the surface of the article or articles being treated on the substrate carrier, or indeed at the substrate carrier itself. For this reason, bias power supplies for the substrate carrier usually include an arc detection circuit, which recognises a rapid increase in current and/or a rapid decrease in voltage as the generation of an arc and interrupts the bias power supply to suppress such arcing.

Although widely used, one of the problems with DC magnetron sputtering is that only a relatively low percentage of the atoms of metal dislodged from the cathode or target are ionised and this restricts the properties of the coating.

In recent times, attempts have been made to overcome the disadvantage of the low degree of ionisation from the sputtered target by applying relatively high power impulses with short duration to the cathodes of the magnetron sputtering system. This is frequently referred to as HIPIMS (High Power Impulse Magnetron Sputtering). For example, powers in the range of megawatts can be applied to the or each cathode over a short time interval of for example 10 μs with a pulse repetition frequency of 500 Hz, that is to say power pulses are applied to the cathode once every 200 ms. By applying power in this way, the cathode changes to a different mode of operation. More specifically, in known regular magnetron sputtering modes using DC sputtering or pulsed DC sputtering, the cathode produces mainly unionised metal vapour.

In contrast, when using highly ionised magnetron sputtering (HIPIMS), the cathode produces ionised metal vapour with very high degrees of ionisation between 40% and 100% being reported. Thus, by applying the high power impulses to the cathode, the cathode changes to a different mode of operation with a high degree of ionisation of the metal vapour originating from it.

Different sources can also lead to high power impulses causing high bias current peaks as well. An example, other than HIPIMS, is pulsed arc sputtering. Here, high current peaks are also generated on the target surface, which also lead to high bias current peaks on the substrate. The height of the current peak on the cathode can, for example, exceed 1000 Amps during short pulse durations whereas, in the time between the pulses on the cathodes, the current can be either zero or have a low value compared to the peak value of the current. In similar manner to the case of HIPIMS, the cathode peak currents are the cause of correspondingly high bias current peaks.

One result of this operation is, however, that the currents which flow at the substrate carrier and at the bias power supply involve current peaks of 40 A or more and this can lead to damage to a conventional bias power supply. Such current levels are interpreted by the bias power supply as the presence of arcing which causes the bias power supply to interrupt the operation in undesired manner.

It would of course be possible to redesign the bias power supply so that it is able to cope with the higher levels of current. However, this can lead to a relatively costly power supply and makes it difficult to ensure interruption of the bias supplied to the substrate carrier in the presence of arcing, which can naturally also occur in the highly ionised magnetron sputtering mode.

Having regard to these problems, the object of the present invention is to provide a vacuum treatment apparatus with a bias power supply adapted to permit a bias current to flow at a level corresponding to the average power level, thus minimising the cost of the bias power supply, but which is nevertheless able to cope with the peak currents arising in a highly ionised magnetron sputtering mode, pulsed arc mode or when using any other possible source which generates very high current peaks with a relatively long duration between the current peaks, and also to permit the detection of undesirable arcing during this mode of operation. Furthermore, the present invention is concerned with providing a power supply for use in such a treatment apparatus and a method of operating such a vacuum treatment apparatus.

In order to satisfy the above objects, there is therefore provided a vacuum treatment apparatus for treating at least one substrate and comprising a treatment chamber, at least one cathode, a power supply associated with the cathode for generating ions of a material present in the gas phase in the chamber and/or ions of a material of which the cathode is formed, a substrate carrier and a bias power supply for applying a negative bias to the substrate carrier and any substrate present thereon, whereby to attract said ions to said at least one substrate, said cathode power supply being adapted to apply relatively high power pulses of relatively short duration to said cathode at intervals resulting in lower average power levels, e.g. comparable to DC operation, e.g. in the range from ca. 1 KW to 100 KW, characterized in that the bias power supply is adapted to permit a bias current to flow at a level corresponding generally to an average power level, and in that an additional voltage supply of relatively low inductive and resistive impedance is associated with the bias power supply for supplying a bias voltage adapted to the power of the relatively high power pulses applied to said at least one cathode.

Furthermore, there is provided a bias power supply in combination with a voltage source for use in such a vacuum treatment apparatus and a method of operating a vacuum treatment apparatus for treating at least one substrate and comprising a treatment chamber, at least one cathode, a power supply associated with the cathode for generating ions of a material present in the gas phase in the chamber and/or ions of a material of which the cathode is formed, a substrate carrier and a bias power supply for applying a negative bias to the substrate carrier and any substrate present thereon, whereby to attract said ions to said at least one substrate, said cathode power supply being adapted to apply relatively high power pulses of relatively short duration to said cathode at intervals resulting in lower average power levels, e.g. comparable to DC operation, e.g. in the range from ca. 1 KW to 100 KW, the method being characterized in that a bias power supply is selected which is adapted to permit a bias current to flow at a level corresponding generally to the average power level or less, and in that an additional voltage supply of relatively low inductive and resistive impedance is provided in association with the bias power supply for supplying a bias voltage adapted to the power of the relatively high power pulses applied to said at least one cathode.

Thus, the present invention is based on the recognition that a conventional bias power supply can be supplemented by an additional voltage supply of relatively low inductive and resistive impedance which is adapted to supply a bias voltage adapted to the power of the relatively high power pulses when the relatively high power pulses are applied to the at least one cathode.

The additional voltage supply, which can for example be a constant voltage supply of some kind, is conveniently formed by a capacitor which can be connected across the output terminals of the bias power supply. Such a capacitor is charged by the bias power supply during intervals between sequential high power pulses applied to the cathode and, when the next high power pulse is applied to the cathode, the capacitor not only maintains the substrate bias voltage within the desired range, but also permits the peak current associated with the high power pulse to flow through the capacitor without substantially affecting the bias power supply. Thus, the voltage source, more particularly the capacitor in the above example, may serve to maintain the desired bias voltage at the substrate carrier and thus the article or articles mounted thereon while permitting a high current to flow during high power peaks of the cathode power supply, but relieves the regular part of the task of delivering the excessively high peak bias current. Instead of using a capacitor as the voltage source or constant voltage source other sources could be used. However, a capacitor is preferred because suitable capacitors are readily available.

To supplement the constant voltage source an arc suppression circuit adapted to detect arcing at the least one substrate can be associated with the bias power supply and adapted to switch off the bias voltage applied to the substrate carrier or to modify the voltage applied to the substrate carrier from the bias power supply and/or from the additional voltage supply.

It is necessary to switch off the substrate arc to prevent the occurrence of damage to the substrate. In the case of arcing, the substrate current reaches very high values.

A convenient arcing suppression circuit can include a switch connected in parallel to at least one of the bias power supply and the additional voltage supply and adapted to switch off the substrate bias voltage or to switch it to a value sufficiently low that the voltage is insufficient to allow arcing to continue. Alternatively, the switch can be connected in series with at least one of the bias power supply and the additional voltage supply to interrupt the bias current flowing to the substrate in the event of arcing. The switch can be a part of the bias power supply, or a part of the additional voltage supply, or indeed a separate unit.

The arcing suppression circuit can monitor at least one of the following parameters:
an unintended low voltage at the substrate holder,
a sharp drop in voltage at the substrate holder, a sharp increase in current to the substrate holder, a current in excess of a maximum current flowing to the substrate holder, the occurrence of pre-specified voltage and/or current patterns at the bias power supply or at the voltage source, and other arcing detection means including optical detectors and electrical noise generation detectors.

The bias power supply can be a DC power supply or a pulsed bias power supply, for example a pulsed bias power supply operating with a frequency (pulse repetition frequency) in the range from 10 to 350 kHz.

In order to further protect the bias power supply it can be convenient to provide a blocking diode in a connection to the bias power supply and/or to the voltage source which only permits current to flow in one direction when using a pulsed bias power supply.

The present invention will now be described in more detail with reference to the accompanying highly schematic drawings in which:

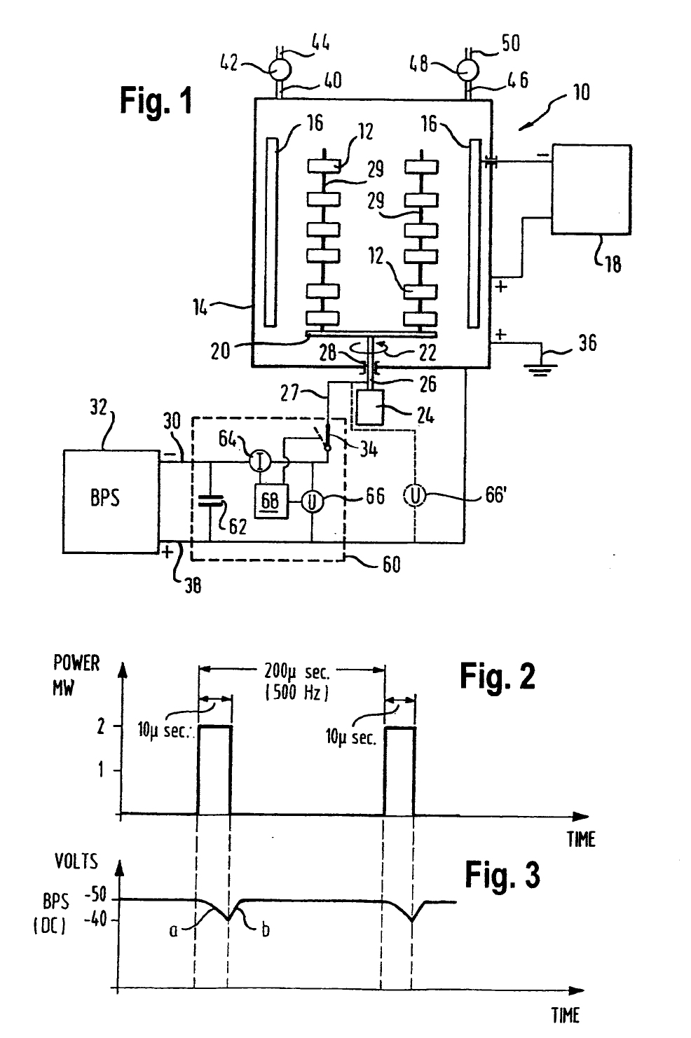

FIG. 1 shows a schematic diagram of a vacuum treatment apparatus equipped with two magnetron sputtering cathodes as seen in a side view,

FIG. 2 shows the typical profile of a high-intensity power supply as applied to the magnetron sputtering cathode of FIG. 1,

FIG. 3 shows a plot of the voltage applied by the bias power supply to the substrate carrier and thus to any article or substrate mounted thereon,

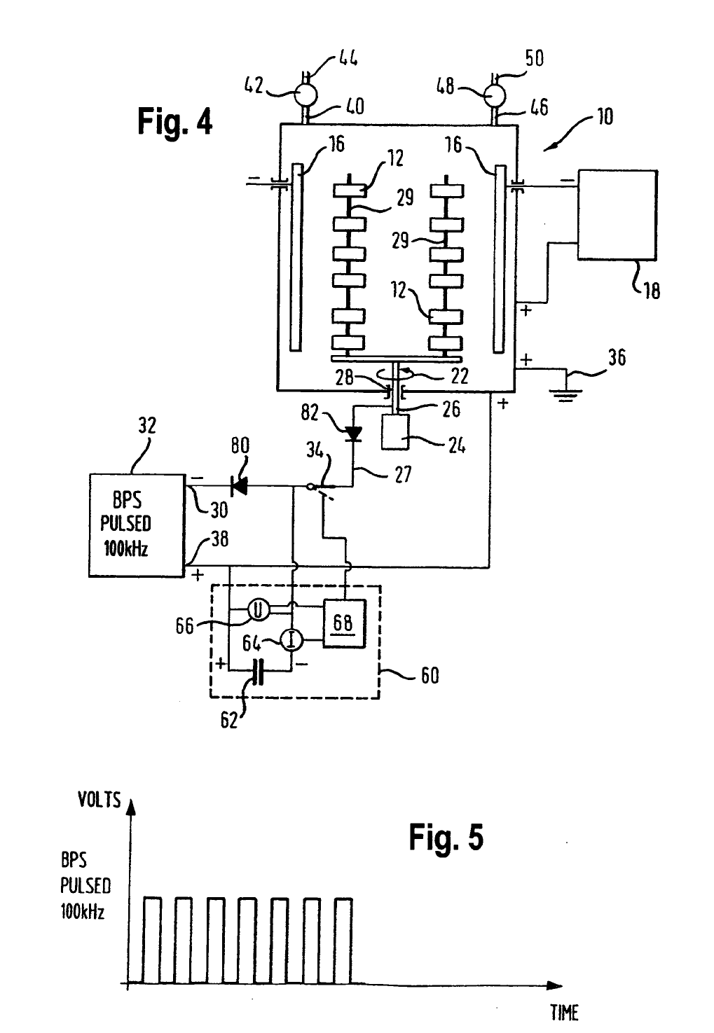

FIG. 4 shows an apparatus similar to that of FIG. 1 but relating to the case of a pulsed DC bias power supply,

FIG. 5 illustrates a voltage plot of a typical pulsed DC bias power supply applied to the substrate carrier of, for example, FIG. 4,

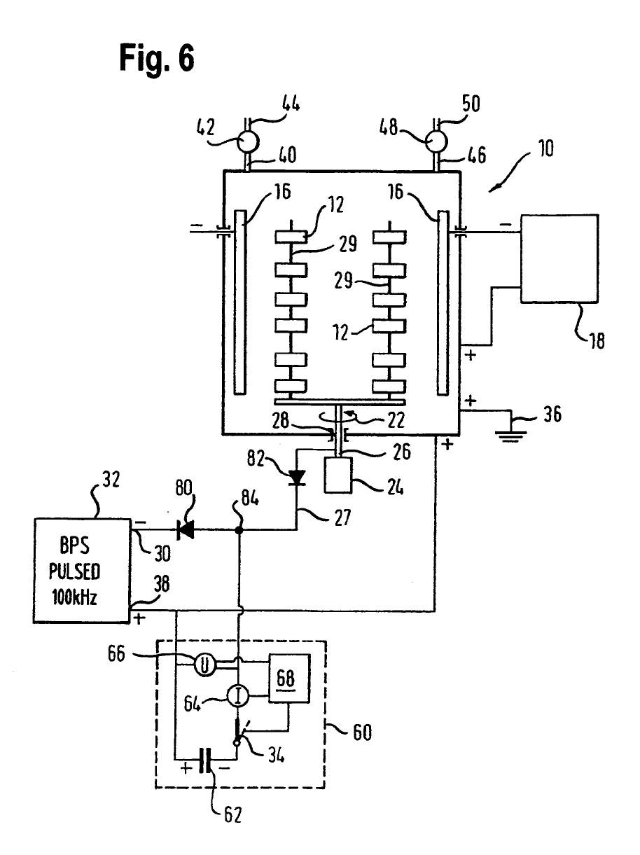

FIG. 6 shows an apparatus similar to that of FIG. 4 but in an alternative layout,

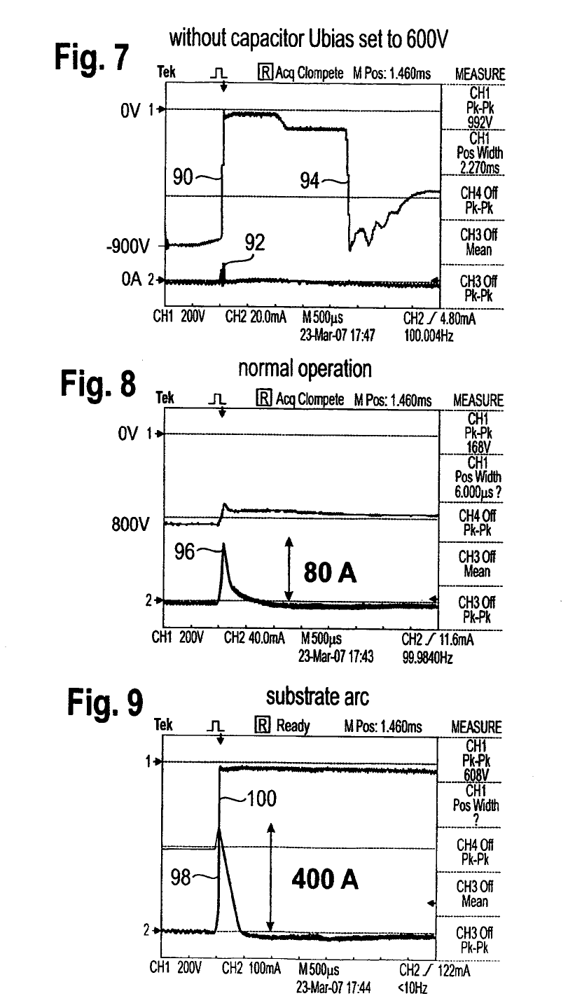

FIG. 7 shows what happens to the bias current when the present invention is not used,

FIG. 8 shows what happens to the bias current when the present invention is used, and

FIG. 9 shows what happens if arcing at the substrate is not detected and prevented.

Turning now to FIG. 1 there can be seen a vacuum treatment apparatus 10 for treating a plurality of substrates 12. The apparatus comprises a treatment chamber 14 of metal which has, in this example, two oppositely disposed cathodes 16 which are each provided with a respective cathode power supply 18 (only one shown) for the purpose of generating ions of a material present in the gas phase in the chamber and/or ions of a material of which the respective cathode or cathodes is formed. The substrates 12 are mounted on a substrate carrier 20 which can be rotated in the direction of the arrow 22 by an electric motor 24 which drives a shaft 26 connected to the substrate carrier. The shaft 26 passes through a lead-through 28 in the wall of the chamber 14 in a sealed and insulated manner which is well known per se. This enables one terminal 30 of the bias power supply 32 to be connected to the shaft 26 via the line 27 and thus to the substrate carrier 20. The substrates 12, which are mounted on the vertical posts 29, are thus maintained at the potential present at the terminal 30 of the bias power supply 32 when the switch 34 is closed.

In this example, the metallic housing 14 of the apparatus 10 is connected to ground 36 which is in fact the positive terminal of the apparatus. The positive terminal of the cathode power supply 18 is also connected to the housing, and thus to ground 36, as is the positive terminal 38 of the bias power supply 32. Not included in the drawings, but also possible, is the connection of the positive terminal of all magnetron power supplies each through blocking diodes to the negative pole of the bias voltage (i.e. the substrate potential), which is a commonly known possible method of connecting the wiring, though not often used because of practical reasons.

Provided at the top of the treatment chamber, although this position is not critical, is a connection stub 40 connected via a valve 42 and a further line 44 to a vacuum system for evacuating the treatment chamber 14. The vacuum system is not shown, but is well known per se in the art. Also connected to the top of the treatment chamber via a stub connection 46 and a valve 48 is a further line 50 which permits one or more appropriate gases to be introduced into the vacuum chamber 14. For example, an inert gas such as argon can be introduced into the vacuum chamber or a gas such as nitrogen or acetylene for the deposition of nitride or carbon coatings or carbonitride coatings. Separate connections similar to 46, 48, 50 can be provided for different gases if required.

Vacuum treatment apparatuses of the kind generally described are well known in the art and are frequently equipped with more than two cathodes 16. For example, a vacuum treatment apparatus is available from the company Hauzer Techno Coating BV in which the chamber 10 has a generally octagonal shape in cross-section with four doors which open outwardly and each of which carries a magnetron cathode 16. These cathodes can be of the same material, but are frequently of different materials to allow coatings of different materials to be built up in layers on the substrates or articles such as 12.

A typical vacuum treatment apparatus also includes a number of other items which are not shown in the schematic drawing of FIG. 1, such as dark field screens, heaters for pre-heating the substrates 12, and sometimes electron beam sources or plasma sources of various designs. In addition, it is possible to include arc cathodes in the vacuum treatment apparatus in addition to the magnetron sputtering cathodes 16.

In use of the apparatus the air initially present in the vacuum chamber 14 is evacuated by the vacuum pumping system via the line 44, the valve 42 and the line 40 and a steady flow of an inert gas, such as argon and/or reactive gases, is passed into the chamber through the line 50, the valve 48 and the connection stub 46. Thus, air present in the chamber is evacuated from and purged from the vacuum chamber 14. At the same time or subsequent to this the heaters (not shown) can be operated to warm the articles 12 and drive off any volatile gases or compounds present at the articles 12.

The inert gas introduced into the chamber will invariably be ionised to some degree, for example due to cosmic radiation, and will split into electrons and inert gas ions, for example argon ions. The argon ions are attracted to the cathodes and collide with the target material knocking out material ions and generating secondary electrons. Associated with each of the cathodes 16 is a magnet system (not shown but well known per se) which typically provides a closed loop magnetic tunnel extending over the surface of the cathode. This closed loop magnetic tunnel causes the electrons to move in tracks generally around the closed loop and produce further ionisation by collisions. These secondary electrons thus cause a further ionisation of the gas atmosphere of the chamber resulting in the generation of further inert gas ions and ions from the material of the target 16. These ions can be attracted towards the articles 12 by an appropriately high substrate bias, e.g. of −200 to −1200 volts, and can be made to impinge thereon with a sufficient energy to etch the surface of the articles.

Once etching has been completed, the coating mode can be initiated in which an appropriate power supply to the cathodes results in a flux of material atoms and ions from the cathode being radiated into the space occupied by the substrates 12 as they rotate on the substrate carrier 20 leading to coating of the substrates. The movement of ions towards the substrates 12 on the substrate carrier 20 is promoted by the negative voltage bias applied to the substrate holder and to the substrates.

Other non-ionised material atoms from the cathodes 16 receive sufficient kinetic energy that they also propagate into the space in front of the cathodes 16 and form a coating on the articles 12. The inert gas ions are also attracted to the articles by the substrate bias and serve to enhance the density of the coating.

It will be appreciated that the bias applied to the substrates is effective to attract ions of the material of the cathode which are knocked out of the surface of the cathode by the ions present in the plasma formed in front of the cathode 16.

Such a sputtering process which proceeds with a constant negative voltage being applied to the cathodes 16 and a constant negative bias being applied to the substrate holder is referred to as DC magnetron sputtering.

Pulsed DC sputtering is also known in which at least one of the cathode power supplies is operated in a pulsed mode. Additionally, the bias power supply for the substrate carrier can be operated in pulsed mode as well.

This can be of advantage in particular with cathodes of a semi-insulating nature.

In such a DC magnetron sputtering process the power applied to each of the cathodes such as 16 can amount to say 16 to 20 kW. For example, four cathodes are typically used in an HTC 1200 vacuum coating machine available from Hauzer Techno Coating BV. This means that a constant current, for example of typically 4-10 A is flowing through the line 27 and through the bias power supply. In other words, in a conventional DC magnetron sputtering apparatus the bias power supply for the substrate holder 20 is designed to operate at a current of up to 4-10 A. Moreover, it includes inbuilt circuitry which detects sudden rises in the current due to arcing which can occur in undesired manner if certain conditions arise in the vacuum chamber 14. In the event of such arcing, the bias power supply is adapted to cease power delivery to allow the arcs to extinguish and then to commence operation again.

As noted above, this well established method of magnetron sputtering has the disadvantage that it is relatively slow and more expensive in comparison to arc cathode technology in which an electric arc is used to dislodge metal ions from the surfaces of the cathodes. On the other hand, it has the advantage that better (smoother) quality coatings can be produced.

Recently, proposals have been made to modify the cathode technology so that instead of providing steady DC power to the cathodes 16, these are now supplied with very high powers as relatively short impulses at relatively long intervals. For example, as illustrated in FIG. 2, the power pulses can have a duration of say 10 μs and a pulse repetition time of 200 μs corresponding to a pulse repetition frequency of 500 Hz, i.e. an interval between sequential pulses of 190 μs. Because the time during which the very high power is applied to the cathodes is restricted, the average power is limited to a moderate level corresponding to the regular magnetron sputtering mode in DC or pulsed DC sputtering. However, by applying the high power impulses to the cathode or cathodes, these change to a different mode of operation in which a very high degree of ionisation of the metal vapour emerging from the cathode or cathodes of between less than 40% and up to 100% arises. Because of this degree of ionisation, many more ions are attracted to the substrates on the substrate carrier and also arrive there with higher speed resulting in denser coatings and more rapid coating deposition.

However, because the power is concentrated into power peaks, a relatively high bias current flows during this time and this current requirement cannot be readily met by a standard bias power supply.

In order to overcome this difficulty, an additional voltage source 60 shown within the dotted rectangle in FIG. 1 is provided. This voltage source 60 principally comprises a capacitor 62 which is charged by a standard bias power supply, or indeed a more simplified bias power supply, to a voltage corresponding to the desired output voltage as determined by the bias power supply. Whenever a power pulse is applied by the cathode power supply 18 to the cathode 16, then this results, as mentioned above, in a flow of material comprised essentially of ions from the cathode 16 to the substrates 12 and this enhancement of ions represents an increased current flow at the substrate holder 20 and through the line 27 corresponding, for example, to about 40 A peak. The normal bias power supply 32 would be incapable of handling such a peak current if designed for regular DC operation instead of high power impulse operation. However, the capacitor which has been charged by the bias power supply, during the intervals between the high power pulses from the cathode power supply 18, is able to maintain the bias voltage at the substrate carrier 20 within close limits and to support such a flow of current which results in slight discharging of the capacitor as shown in the drawing of FIG. 3 where it can be seen that the charged voltage across the capacitor, shown in this example as being −50 V, has reduced to say −40 V within the 10 ms duration of the high power pulse from the cathode power supply 18 to the cathode 16 (see section “a” of the curve of FIG. 3). Once this pulse ceases, the capacitor again charges up to the −50 V level and has reached this level shortly after the termination of the high power pulse (see section “b” of the curve of FIG. 3. This power level is maintained until another power impulse arises from the power supply 18 to the cathode 16 (or from another power supply to another one of the other cathodes 16) and then drops again to −40 V over the duration of the high power pulse before recharging starts again.

It should be noted that similar undesired voltage drops will occur while the system is etching, i.e. bias voltages are at much higher levels, say between less than 700 V up to 1200 V and higher. It will be appreciated that the capacitor provides only a low impedance to the current flowing so that the current flowing is short-circuited through the capacitor rather than flowing through the higher impedance of the bias power supply. It should be appreciated that although the peak flow of ions to the substrates occurs during the power peak applied by the cathode power supply to the cathode this does not mean that the flow ceases as soon as the power peak is over. Instead it is entirely possible that the flux of ions continues, albeit at a reduced level with reduced current, during the intervals between successive power peaks, where the applied power on the cathodes is much lower.

Additionally, it must be remarked here that instead of using pulsed sputter cathodes, all different types of pulsing cathodes/sources acting on biased substrates can be used here as well. An example might be for instance pulsed arc cathodes.

Naturally, it is also possible for arcing to take place in the treatment chamber with the system just described. In this case, the arcing further modifies various operating parameters of the system, for example the current flowing in the line 27 and the voltage across the capacitor 62. Thus, detectors can be provided, such as 64, which detects the current flowing in the line 32, and 66, which detects the voltage across the capacitor and the output signals from these detectors can be fed to an arcing suppression circuit 68 which is connected to operate a semiconductor switch shown schematically at 34 in FIG. 1. Thus, if the arcing detection circuit detects values of current and/or voltage which indicate the presence of arcing at the articles 12 or at the substrate carrier 20, then the arcing suppression circuit operates to open the switch 34, thus interrupting the bias voltage present at the substrate carrier 20 and at the substrates 12 and leading to prompt extinguishing of the arc. The broken line including the detector 66′ shows an alternative position for the voltage detector 66, i.e. directly between the line 27 and the positive terminal of the bias power supply 32, i.e. on the other side of the switch 34 from the detector 66. The position shown for the detector 66′ is the preferred position.

In this embodiment the arc suppression circuit is included in the voltage source 60, it could however be a module separate from the voltage source 60 or incorporated into the bias power supply 32.

Turning now to FIGS. 7, 8 and 9, the operation of the invention will be explained from a different point of view.

FIG. 7 shows the situation when a conventional bias power supply is used without the additional power supply represented by the capacitor 62 in accordance with the invention. The conventional power supply is equipped with an arc protection circuit.

For this example the average bias voltage applied to the substrate is set at −600 V.

When the cathode is operated in the HIPIMS mode, a high power pulse supplied to the cathode results, after a short time delay, in a high current starting to appear at the substrates. This high current is interpreted as an arc by the arc protection circuit and the arc protection circuit and the bias power supply immediately switches off the bias voltage, shown by the strong rise in bias voltage from approximately −900 V to approximately 0 V as shown by the reference numeral 90 in FIG. 7. The bias current at the substrate, which is shown by the lower curve in FIG. 7 and which has an average value of 0 A, simply shows a short peak 92 aligned timewise with the sharp change in bias voltage 90. This will be understood to mean that hardly any bias current flows and indeed because the bias voltage has been switched off (90). At a later stage, the bias voltage rises again (94) but can no longer lead to significant current flowing at the substrates because the high power pulse (current pulse) applied to the cathode has long since passed. Thus, an apparatus of this kind will be ineffective for HIPIMS sputtering.

FIG. 8 shows the situation for HIPIMS sputtering using the additional capacitor 62, i.e. the additional voltage supply in accordance with the present invention. Using the capacitor 62 of FIG. 1, the bias current peak can form automatically in a natural manner at the appropriate time (after the time delay between the power peak applied to the cathode and the burst of ions reaching the substrates. It can be seen from the upper curve, which again shows the bias voltage, that this only changes insignificantly due to the effect of the capacitor 62. Thus, current is able to flow to the substrates in the required manner following each high power pulse supplied to the cathode.

If the circuit of the invention were operated without arc protection, then, in the event of an arc, for example because the arc protection circuit recognises currents above 80 A as an arc, a very high current peak arises, here shown as 98, of approximately 400 A and this could cause damage to the substrates being coated and possibly damage to the bias power supply. It will be seen that the high current peak would again lead to a significant reduction of the bias voltage at 100, again corresponding to the development of an arc and able to be detected in order to activate the arc suppression circuit embodied in the apparatus of the present invention as described with reference to FIG. 1.

Turning now to FIG. 4 there can be seen an embodiment in which the constant voltage source is used with a bias power supply which transmits unipolar voltage bias pulses to the substrate carrier 20 as shown in FIG. 5. The pulses are rectangular pulses, with a pulse repetition frequency of 100 kHz and a mark/space ratio of 1 (although this is not essential).

Other wave forms could also be used and the pulses could also be bipolar rather than unipolar. The apparatus of FIG. 4 is largely similar to the apparatus of FIG. 1 and the description given for FIG. 1 also applies to the apparatus of FIG. 4, and indeed also to the apparatus of FIG. 6, so that this description will not be unnecessarily repeated here. In distinction to the embodiment of FIG. 1, the embodiment of FIG. 4 however includes two diodes 80, 82. The diode 80 ensures that current can only flow in one direction through the bias power supply, thus allowing the capacitor to be charged in one direction to the peak voltage of the pulsed voltage form shown in FIG. 5. The further diode 82, which could however be omitted, allows the capacitor to be discharged during high power impulse peaks from the cathode power supply 18. It is important here that pulsing of the bias power supply requires that the switch 34 starts acting independently to pulse the capacitor voltage as well at the same frequency as required for the bias power supply.

The arcing suppression circuit in FIG. 4 is similar to that in FIG. 1 and again includes a sensor 66 for the voltage U present across the capacitor and a sensor 64 for the current flowing through the capacitor. Again, these two sensors are connected to the arcing suppression circuit 68 and the arcing suppression circuit is able to trigger the electronic switch 34 to disconnect the bias power supply 32 from the substrate carrier 20. A further difference which needs to be taken into account when using pulsed bias is that the serial switch 34, needed to switch off an arc discharge on the substrate, must be switched off and on synchronized with the pulsing of the regular bias power supply. This is needed, since due to the presence of the capacitance, there will be no pulsing available on the substrate, since the capacitor would stay at a constant voltage level. Only by switching switch 34 can the substrate bias voltage be pulsed.

As noted above, the embodiment of FIG. 6 is also closely similar to that of FIG. 4 and indeed the only difference here is that the switch 34 controlled by the arcing suppression circuit is now connected in series with the capacitor in the circuit parallel to the bias power supply 32, i.e. between the capacitor and the node 84, rather than in the line or lead 27 between the node 84 and the shaft 26.

It will be apparent to one skilled in the art that various modifications are possible. For example, the arcing suppression circuit can operate not only by reference to the voltage present at the voltage sensor or by the current present at the current sensor 64. In principle, the arcing suppression circuit could monitor at least one of the following parameters: an unintended low voltage at the substrate holder 20, a sharp drop in voltage at the substrate holder 20, a sharp increase in current to the substrate holder, a current in excess of a maximum current flowing to the substrate holder, the occurrence of pre-specified voltage and/or current patterns at the bias power supply or at the voltage source. The arcing suppression circuit could also be responsive to signals from other arcing detection means including optical detectors and electrical noise generation detectors. The voltage source is preferably a constant voltage source, and in the simplest case, a capacitor as shown in the examples of FIGS. 1, 4 and 6.

Moreover, although the invention is principally intended for use with magnetron sputtering apparatus, it is also conceivable that it could be used in other forms of vacuum treatment apparatus where similar problems arise. Additionally, it must be remarked here that instead of using pulsed sputter cathodes, all different types of pulsing cathodes/ sources acting on biased substrates can be used here as well. An example might be for instance pulsed arc cathodes.

1-17. (canceled)

18. A vacuum treatment apparatus (10) for treating at least one substrate (12) and comprising a treatment chamber (14), at least one cathode (16), a power supply (18) associated with the cathode for generating ions of a material present in the gas phase in the chamber and/or ions of a material of which the cathode is formed, a substrate carrier (20) and a bias power supply (32) for applying a negative bias to the substrate carrier and any substrate present thereon, whereby to attract said ions to said at least one substrate, said cathode power supply (18) being adapted to apply relatively high power pulses of relatively short duration to said cathode at intervals resulting in lower average power levels comparable with DC operation, e.g. in the range from ca. 1 KW to 100 KW,
characterized in that
the bias power supply (32) is adapted to permit a bias current to flow at a level corresponding generally to the average power level, and
in that an additional voltage supply (60) of relatively low inductive and resistive impedance is associated with the bias power supply (32) for supplying a bias voltage adapted to the power of the relatively high power pulses when said relatively high power pulses are applied to said at least one cathode (16).

19. A vacuum treatment apparatus in accordance with claim 18, characterized in that an arcing suppression circuit (68) adapted to detect arcing at the at least one substrate (12) is associated with the bias power supply and is adapted to modify the voltage applied to the substrate carrier (20) from the bias power supply (32) and/or from the additional voltage supply (60).

20. A vacuum treatment apparatus in accordance with claim 18, characterized in that the arcing suppression circuit (68) includes a switch (34) connected in parallel to at least one of the bias power supply (32) and the additional voltage supply (60) to reduce the value of the substrate bias voltage to a value sufficiently low that the voltage is insufficient to allow arcing to continue.

21. A vacuum treatment apparatus in accordance with claim 18, characterized in that the arcing suppression circuit includes a switch (34) connected in series with at least one of the bias power supply (32) and the additional voltage supply (60) to interrupt the bias current flowing to the substrate (12) in the event of arcing.

22. A vacuum treatment apparatus in accordance with claim 20, characterized in that the switch (34) is a part of the bias power supply (32) or is a part of the additional voltage supply (60) or is a separate unit.

23. A vacuum treatment apparatus in accordance with claim 21, characterized in that the switch (34) is a part of the bias power supply (32) or is a part of the additional voltage supply (60) or is a separate unit.

24. A vacuum treatment apparatus in accordance with claim 19, characterized in that the arcing suppression circuit (68) monitors at least one of the following parameters:
an unintended low voltage at the substrate holder,
a sharp drop in voltage at the substrate holder, a sharp increase in current to the substrate holder, a current in excess of a maximum current flowing to the substrate holder, the occurrence of pre-specified voltage and or current patterns at the bias power supply or at the voltage source, or comprises other arcing detection means including optical detectors and electrical noise generation detectors.

25. A vacuum treatment apparatus in accordance with claim 18, characterized in that the voltage source (60) is a constant voltage source.

26. A vacuum treatment apparatus in accordance with claim 18, characterized in that said voltage source (60) is a capacitor (62).

27. A vacuum treatment apparatus in accordance with claim 18, characterized in that said voltage source (60) is charged by said bias power supply (32).

28. A vacuum treatment apparatus in accordance with claim 18, characterized in that said bias power supply (32) is a DC power supply.

29. A vacuum treatment apparatus in accordance with claim 18, characterized in that said bias power supply (32) is a pulsed bias power supply, e.g. a pulsed bias power supply operating with a frequency in the range from 10 to 350 kHz.

30. A vacuum treatment apparatus in accordance with claim 29, characterized in that at least one blocking diode (80) is provided in a connection to said bias power supply (32) and/or to said voltage source (60).

31. A vacuum treatment apparatus (10) for treating at least one substrate (12) and comprising a treatment chamber (14), at least one cathode (16), a power supply (18) associated with the cathode for generating ions of a material present in the gas phase in the chamber and/or ions of a material of which the cathode is formed, a substrate carrier (20) and a bias power supply (32) for applying a negative bias to the substrate carrier and any substrate present thereon, whereby to attract said ions to said at least one substrate, said cathode power supply (18) being adapted to apply relatively high power pulses of relatively short duration to said cathode at intervals resulting in lower average power levels comparable with DC operation,
characterized in that
a bias power supply (32) is provided which is adopted to operate at a relatively low bias current and is used in combination with an additional voltage supply charged by the bias power supply and of relatively low inductive and resistive impedance, said additional voltage supply being provided for supplying a bias voltage adapted to the power of the relatively high power pulses when said relatively high power pulses are applied to said at least one cathode (16).

32. A bias power supply (32) in combination with a voltage source (60) for use in a vacuum treatment apparatus (10) for treating at least one substrate (12) and comprising a treatment chamber (14), at least one cathode (16), a power supply (18) associated with the cathode for generating ions of a material present in the gas phase in the chamber and/or ions of a material of which the cathode is formed, a substrate carrier (20) and a bias power supply (32) for applying a negative bias to the substrate carrier and any substrate present thereon, whereby to attract said ions to said at least one substrate, said cathode power supply (18) being adapted to apply relatively high power pulses of relatively short duration to said cathode at intervals resulting in lower average power levels comparable with DC operation, e.g. in the range from ca. 1 KW to 100 KW,
characterized in that
the bias power supply (32) is adapted to permit a bias current to flow at a level corresponding generally to the average power level, and
in that an additional voltage supply (60) of relatively low inductive and resistive impedance is associated with the bias power supply (32) for supplying a bias voltage adapted to the power of the relatively high power pulses when said relatively high power pulses are applied to said at least one cathode (16).

33. A method of operating a vacuum treatment apparatus (10) for treating at least one substrate (12) and comprising a treatment chamber (14), at least one cathode (16), a power supply (18) associated with the cathode for generating ions of a material present in the gas phase in the chamber and/or ions of a material of which the cathode is formed, a substrate carrier (20) and a bias power supply (32) for applying a negative bias to the substrate carrier (20) and any substrate (12) present thereon, whereby to attract said ions to said at least one substrate, said cathode power supply (18) being adapted to apply relatively high power pulses of relatively short duration to said cathode at intervals resulting in lower average power levels comparable with DC operation, e.g. in the range from ca. 1 KW to 100 KW, the method being
characterized in that
a bias power supply (32) is selected which is adapted to permit a bias current to flow at a level corresponding generally to the average power level, and in that an additional voltage supply (60) of relatively low inductive and resistive impedance is provided in association with the bias power supply (32) for supplying a bias voltage adapted to the power of the relatively high power pulses when said relatively high power pulses are applied to said at least one cathode.

34. A method in accordance with claim 33 and further characterized by the step of charging the further voltage source (60) from said bias power supply (32) during intervals between peaks of said high power pulses applied to said cathode (16).
